(19) United States
(12) Patent Application Publication
(10) Pub. No.: US 2009/0189635 A1
(43) Pub. Date: Jul. 30, 2009

(54) METHOD AND APPARATUS FOR IMPLEMENTING REDUCED COUPLING EFFECTS ON SINGLE ENDED CLOCKS

(76) Inventors: Roger Allen Booth, JR., Wappingers Falls, NY (US); John Richard Dangler, Rochester, MN (US); Matthew Stephen Doyle, Rochester, MN (US); Jesse Hefner, Rochester, MN (US); Thomas W. Liang, Rochester, MN (US); Ankur Kanu Patel, Rochester, MN (US); Paul W. Rudrud, Rochester, MN (US)

Correspondence Address: IBM CORPORATION;ROCHESTER IP LAW DEPT 917, 3605 HIGHWAY 52 N, ROCHESTER, MN, 55901-7829, US

(21) Appl. No.: 12/020,727

(22) Filed: Jan. 28, 2008

(51) Int. Cl. H03K 19/003

(52) U.S. Cl. 326/22

(57) ABSTRACT

A method and apparatus implement reduced noise coupling effects on single ended clocks, and a design structure on which the subject circuit resides is provided. A clock receiver includes a clock voltage reference that is generated from received clock peaks and valleys of a received input clock signal. The received clock peaks (VT) and the received clock valleys (VB) are continuously sampled. The clock voltage reference is set, for example, equal to an average of VT and VB; or ((VT+VB)/2).

### FIELD OF THE INVENTION

The present invention relates generally to the data processing field, and more particularly, relates to a method and apparatus for implementing reduced noise coupling effects on single ended clocks, and a design structure on which the subject circuit resides.

### DESCRIPTION OF THE RELATED ART

Common mode noise is currently a significant source of clock arrival skew. FIGS. 1A, 1B, and 1C illustrate the effects of coupled noise on single-ended clocks.

FIG. 1A illustrates a quiet single ended clock signal at a receiver. FIG. 1C illustrates the single ended clock signal with coupled noise at a receiver. FIG. 1B illustrates that the same coupled noise does not affect a differential clock signal.

Methods exist to reduce the effects of coupled noise on clock latch timing, such as clock voltage reference forwarding schemes. Improved skew reduction methods are necessary because known solutions fail to eliminate received clock skew.

A need exists for an effective mechanism for implementing reduced noise coupling effects on single ended clocks.

### SUMMARY OF THE INVENTION

Principal aspects of the present invention are to provide a method and apparatus for implementing reduced noise coupling effects on single ended clocks. Other important aspects of the present invention are to provide such method and apparatus for implementing reduced coupling effects on single ended clocks substantially without negative effect and that overcome many of the disadvantages of prior art arrangements.

In brief, a method and apparatus for implementing reduced noise coupling effects on single ended clocks, and a design structure on which the subject circuit resides are provided. A clock receiver includes a clock voltage reference that is generated from received clock peaks and valleys of a received input clock signal. The received clock peaks (VT) and the received clock valleys (VB) are continuously sampled. The clock voltage reference is set equal to the average of VT and VB.

In accordance with features of the invention, the clock voltage reference more closely tracks the intended switch point, so that skew between transmitted and received clock edges is significantly reduced.

In accordance with features of the invention, for example, the clock voltage reference is set equal to ((VT+VB)/2).

In accordance with features of the invention, alternatively, the clock voltage reference is set so that a rising voltage reference is generated by adding half of a peak to peak voltage to the sampled received clock valleys VB and the falling voltage reference is generated by subtracting half of the peak to peak voltage from the sampled received clock peaks VT.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1A, 1B, and 1C are diagrams illustrating prior art clock receiver operation;

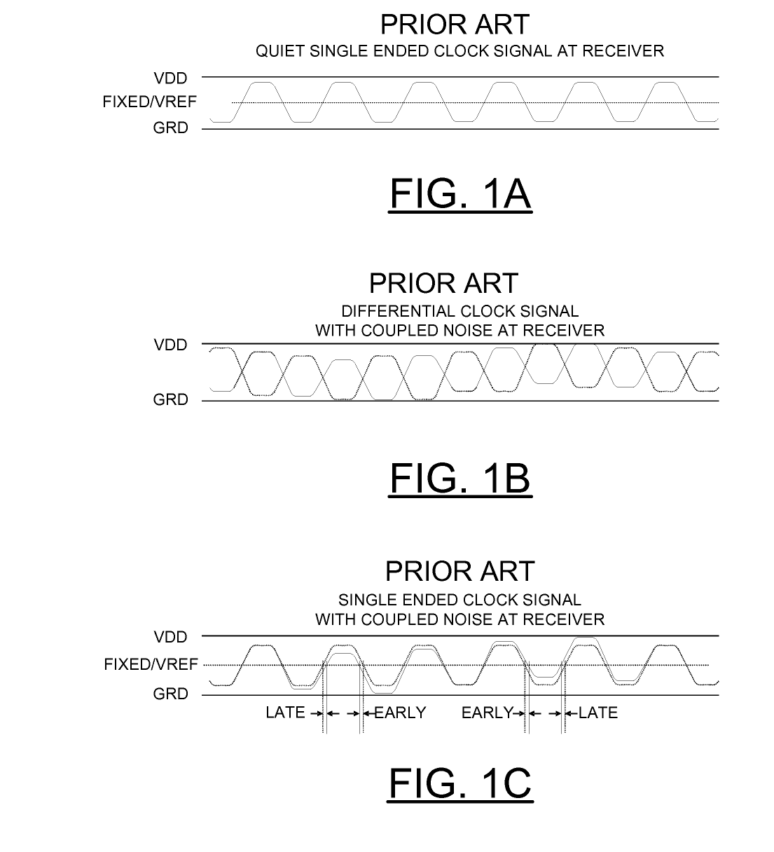

FIGS. 2A and 2B are diagrams illustrating operation of a clock receiver in accordance with the preferred embodiment;

FIGS. 3A and 3B are diagrams illustrating alternative operation of a clock receiver in accordance with the preferred embodiment;

FIG. 4A is a schematic diagram representation illustrating an exemplary receiver in accordance with the preferred embodiment;

FIGS. 4B and 4C are schematic diagrams representation illustrating prior art receivers;

FIG. 5 is a diagram illustrating a respective receiver input of the receiver of FIG. 4A in accordance with the preferred embodiment, and the prior art receivers of FIGS. 4B and 4C;

FIG. 6 is a diagram illustrating operation of a sample and hold of the receiver of FIG. 4A in accordance with the preferred embodiment;

FIG. 7 is a diagram illustrating operational input and reference (VREF) voltages of the receiver of FIG. 4A in accordance with the preferred embodiment,

FIG. 8 is a diagram illustrating a respective eye diagram of respective receiver output of the receiver of FIG. 4A in accordance with the preferred embodiment, and the prior art receivers of FIGS. 4B and 4C; and

FIG. 9 is a flow diagram of a design process used in semiconductor design, manufacturing, and/or test.

### DETAILED DESCRIPTION OF THE PREFERRED EMBODIMENTS

In accordance with features of the invention, a method is provided to reduce the effects of coupled noise on single ended clocks. A clock voltage reference VREF is based upon the received clock peaks and valleys of a received input clock signal. As a result the clock voltage reference more closely tracks the intended switch point, so that clock skew between transmitted and received clock edges is significantly reduced.

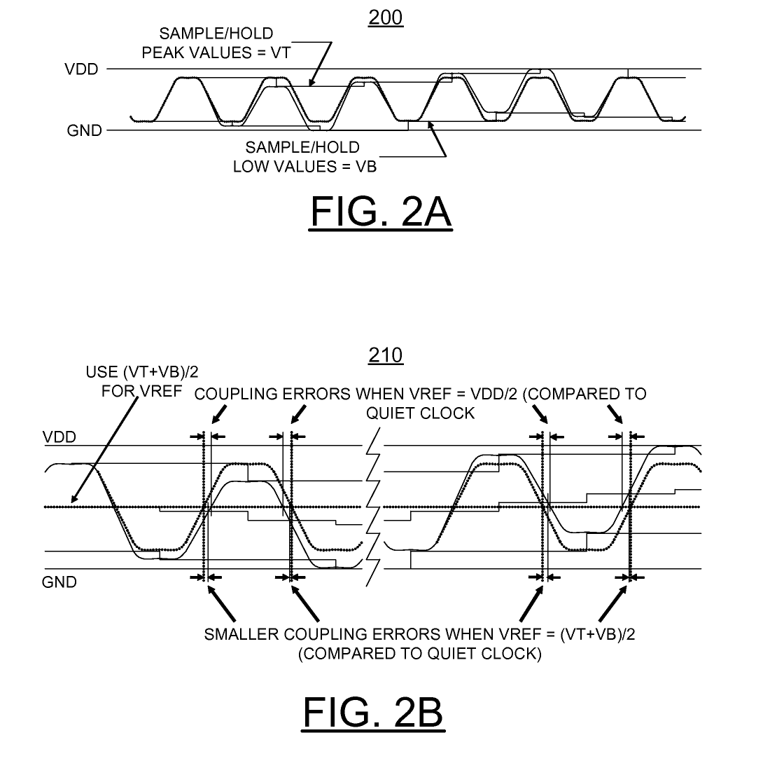

Having reference now to the drawings, in FIGS. 2A and 2B, there are shown diagrams respectively generally designated by the reference characters 200, 210 providing a graphical view of the invention illustrating operation of a clock receiver in accordance with the preferred embodiment.

FIG. 2A provides an example single ended clock signal 200 with coupled noise of a received input clock signal. Continuously sampling of the received clock peaks and the received clock valleys is indicated by lines respectively labeled SAMPLE/HOLD PEAK VALUES=VT and SAMPLE/HOLD LOW VALUES=VB.

An alternate VREF indicated by ((VT+VB)/2 is generated from the received peak values VT and valley low values VB, for example, as shown in FIG. 2B and clearly depicts how the present invention more closely tracks the intended switch point of the clock signal, removing some of the effects of coupled noise above and beyond the conventional VREF=VDD/2 arrangements.

As shown in FIG. 2B, VREF is generated by continuously sampling the received clock peaks (VT) and the received clock valleys (VB). The clock voltage reference VREF is set equal to the average of VT and VB represented by ((VT+VB)/2.

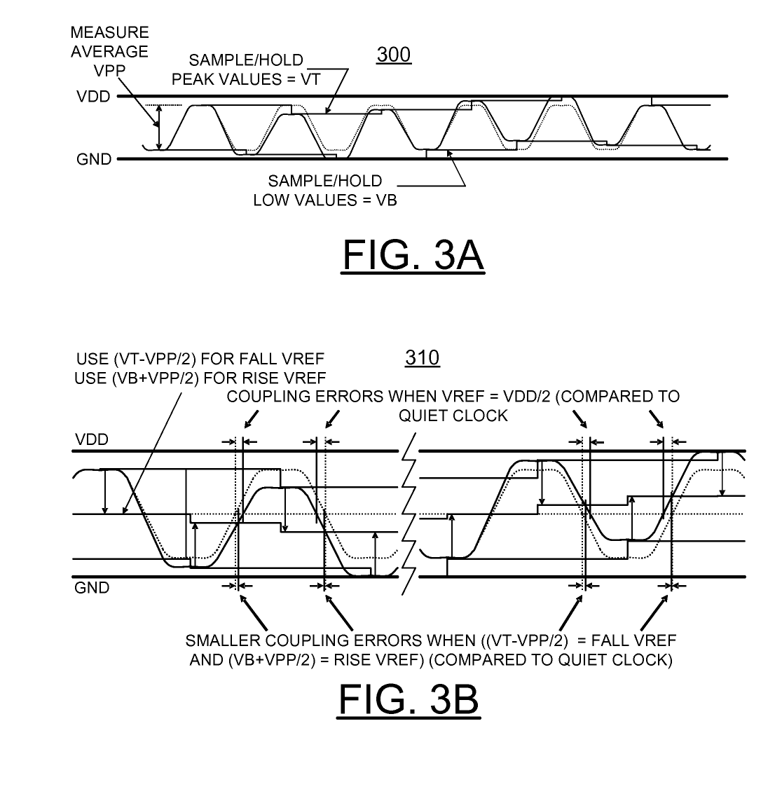

Referring now to FIGS. 3A and 3B, there are shown diagrams respectively generally designated by the reference characters 300, 310 providing a graphical view of the invention illustrating operation of a clock receiver in accordance with the preferred embodiment.

FIG. 3A provides an example single ended clock signal 300 with coupled noise of a received input clock signal. Continuously sampling of the received clock peaks and the received clock valleys is indicated by lines respectively labeled SAMPLE/HOLD PEAK VALUES=VT and SAMPLE/HOLD LOW VALUES=VB. A measured average peak to peak voltage MEASURE AVERAGE VPP is shown in FIG. 3A that is used to generate a FALL VREF and a RISE VREF, as shown in FIG. 3B.

As shown in FIG. 3B, VREF is generated by continuously sampling the received clock peaks (VT) and the received clock valleys (VB), and the measured average peak to peak voltage MEASURE AVERAGE VPP. An alternate respective FALL VREF indicated by (VT-VPP/2) and RISE VREF indicated by (VB+VPP/2) is generated from the received peak values VT and valley low values VB and also depicts how the present invention more closely tracks the intended switch point of the clock signal, removing some of the effects of coupled noise above and beyond the conventional VREF=VDD/2 arrangements.

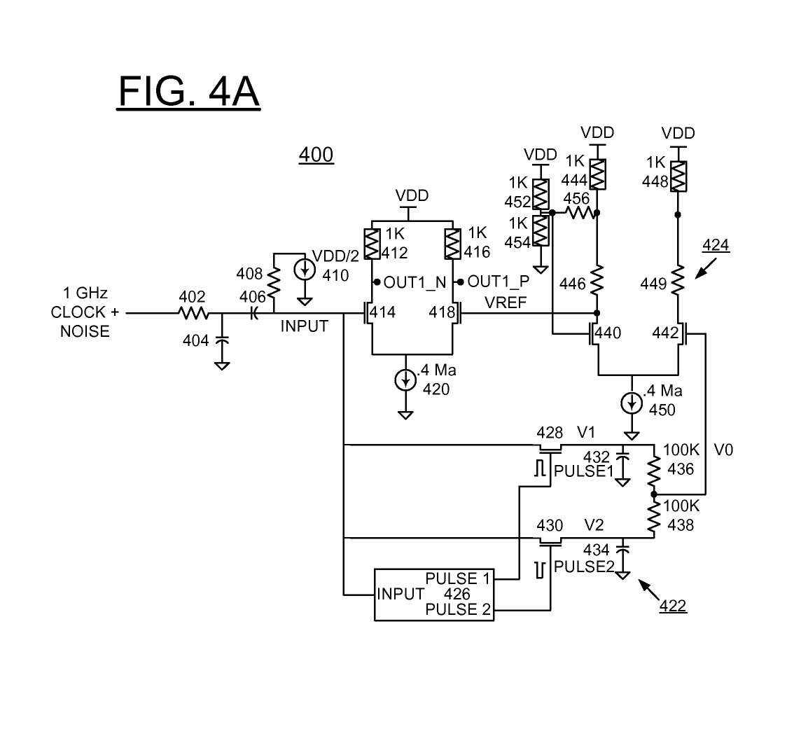

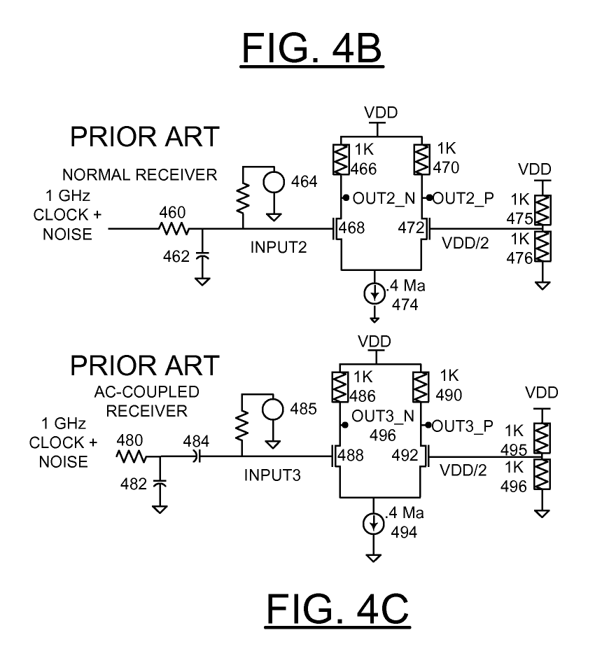

Referring now to FIG. 4A, there is shown an exemplary receiver generally designated by the reference character 400 in accordance with the preferred embodiment. Clock receiver 400 in accordance with the preferred embodiment is an AC-coupled and voltage reference adjusted receiver.

Clock receiver 400 receives a single ended clock signal with coupled noise indicated by 1 GHz CLOCK+NOISE applied to an input resistor 402 connected to a capacitor 404 connected to ground potential and an AC coupling capacitor 406 providing an input clock signal at a node INPUT. A resistor 408 and voltage source 410 VDD/2 is connected between ground potential and node INPUT. A respective receiver output OUT1_N, OUT1_P is provided at a respective junction connection of a resistor 412 and an N-channel field effect transistor (NFET) 414, and a resistor 416 and an NFET 418, connected between a voltage supply rail VDD and a current source 420 connected to ground potential.

Clock receiver 400 in accordance with the preferred embodiment includes a sample and hold generally designated by the reference character 422 and a unity gain buffer generally designated by the reference character 424 providing a clock voltage reference VREF that is based upon the received clock peaks and valleys of the received input clock signal at node INPUT.

Sample and hold 422 receives the input clock signal INPUT at pulse generator block 426 and provides outputs PULSE1, PULSE2 continuously sampling of the received clock peaks and the received clock valleys. Sample and hold 422 includes a first NFET 428 and a second NFET 430 connected between node INPUT and a respective node V1, V2 receive a respective gate input PULSE1, PULSE2. A respective capacitor 432, 434 is connected between the respective node V1, V2 and ground potential. A voltage divider defined by series connected resistors 436, 438 is connected between the nodes V1, V2 and provides a sample and hold output voltage at node V0.

The unity gain buffer 424 includes a pair of NFETs 440, 442 respectively connected between the voltage supply rail VDD via a respective pair of series connected resistors 444, 446, and 448, 449 and a current source 450 connected to ground potential. The unity gain buffer 424 includes a voltage divider defined by a pair of series connected resistors 452, 454 connected between the voltage supply rail VDD and ground potential. A resistor 456 is connected between a respective junction connection of resistors 452, 456 and resistor 444, 446. The junction connection of resistors 452, 456 is applied to a gate of NFET 440. The sample and hold output voltage at node V0 is applied to a gate of NFET 442. The clock voltage reference VREF generated at the drain of NFET 440 of the unity gain buffer 424 is applied to the gate of NFET 418.

FIG. 4B illustrates a first prior art normal receiver that receives the single ended clock signal with coupled noise indicated by 1 GHz CLOCK+NOISE applied to an input resistor 460 connected to a capacitor 462 connected to ground potential and providing an input clock signal at a node INPUT2. A resistor and voltage source 464 is connected between ground potential and node INPUT2. A respective receiver output OUT2_N, OUT2_P is provided at a respective junction connection of a resistor 466 and an NFET 468, and a resistor 470 and an NFET 472, connected between the voltage supply rail VDD and a current source 474 connected to ground potential. A voltage divider defined by a pair of series connected resistors 475, 476 connected between the voltage supply rail VDD and ground potential provides a voltage reference VDD/2 to a gate of NFET 472.

FIG. 4C illustrates a prior art AC-coupled receiver that receives the single ended clock signal with coupled noise indicated by 1 GHz CLOCK+NOISE applied to an input resistor 480 connected to a capacitor 482 connected to ground potential and an AC coupling capacitor 484 providing an input clock signal at a node INPUT3. A resistor and voltage source 485 is connected between ground potential and node INPUT3. A respective receiver output OUT3_N, OUT3_P is provided at a respective junction connection of a resistor 486 and an NFET 488, and a resistor 490 and an NFET 492, connected between the voltage supply rail VDD and a current source 494 connected to ground potential. A voltage divider defined by a pair of series connected resistors 495, 496 connected between the voltage supply rail VDD and ground potential provides a voltage reference VDD/2 to a gate of NFET 492.

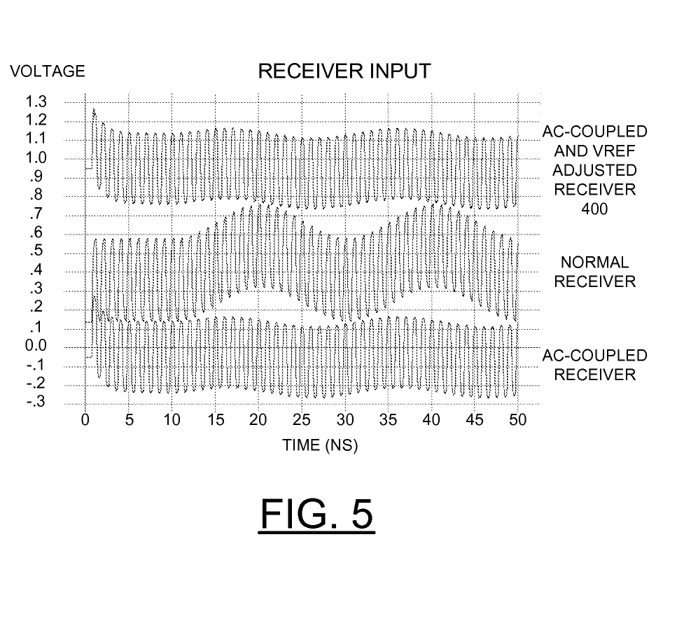

Referring also to FIGS. 5, 6, 7 and 8, operation of the AC-coupled and VREF adjusted receiver 400 of FIG. 4A in accordance with the preferred embodiment may be understood with respect to the prior art receivers illustrated in FIGS. 4B and 4C.

FIG. 5 illustrates a receiver input INPUT of the receiver 400 of FIG. 4A in accordance with the preferred embodiment indicated by AC-COUPLED AND VREF ADJUSTED RECEIVER 400 for comparison with the receiver inputs INPUT2, INPUT3 of the prior art receivers of FIGS. 4B and 4C respectively indicated by NORMAL RECEIVER, and AC-COUPLED RECEIVER.

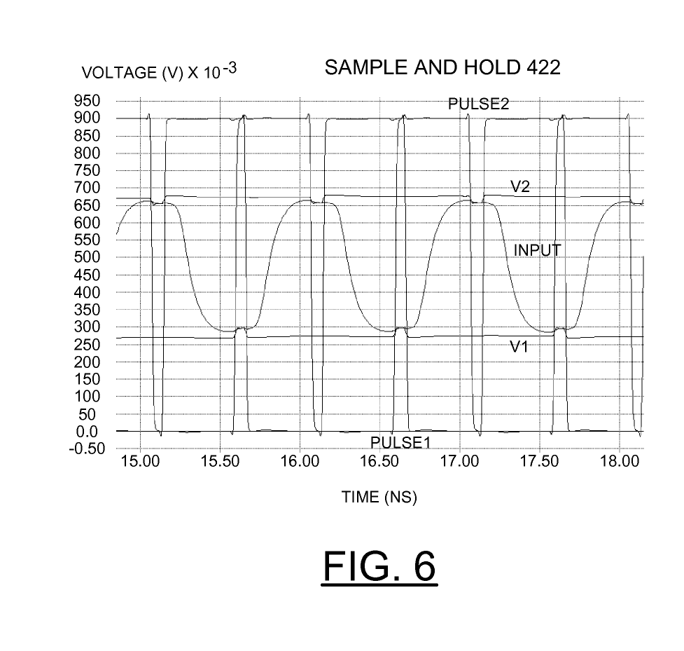

FIG. 6 illustrates operation of the sample and hold 422 of the receiver 400 of FIG. 4A in accordance with the preferred embodiment. An exemplary input labeled INPUT, sampling pulses PULSE1, PULSE2, and reference voltages V1, V2 are shown.

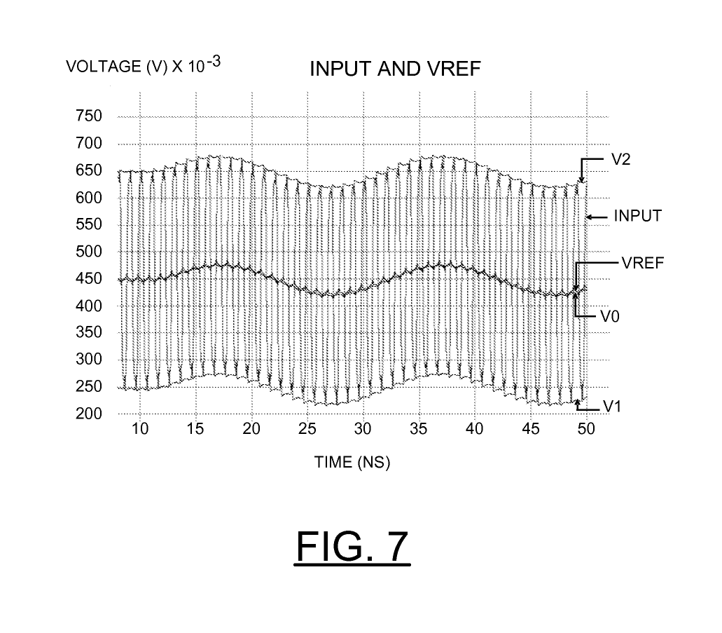

FIG. 7 illustrates exemplary operational input and reference (VREF) voltages VREF, V0, V1, V2 of the receiver 400 of FIG. 4A in accordance with the preferred embodiment.

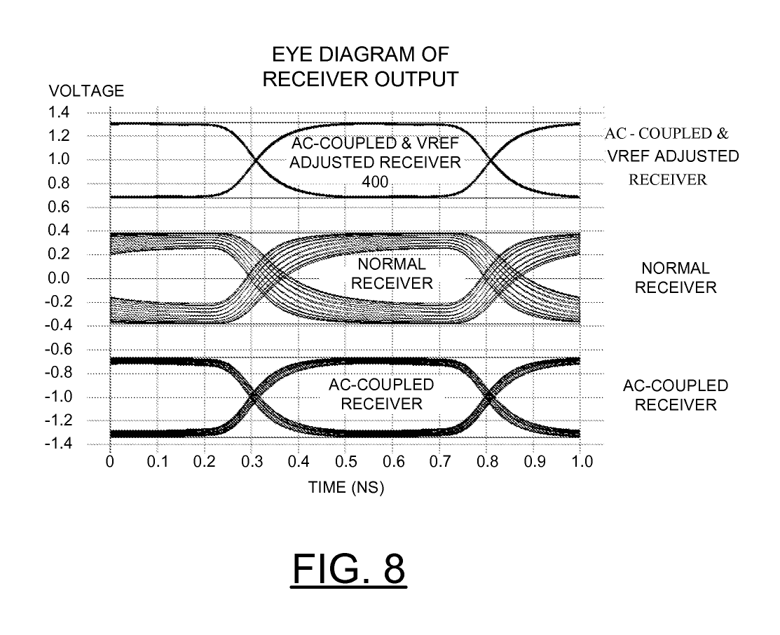

FIG. 8 is a diagram illustrating a respective eye diagram of respective receiver output of the receiver 400 of FIG. 4A in accordance with the preferred embodiment for comparison with the prior art receivers of FIGS. 4B and 4C. As seen from the illustrated eye diagrams, the receiver output of the receiver 400 of FIG. 4A in accordance with the preferred embodiment clearly removes some of the effects of coupled noise.

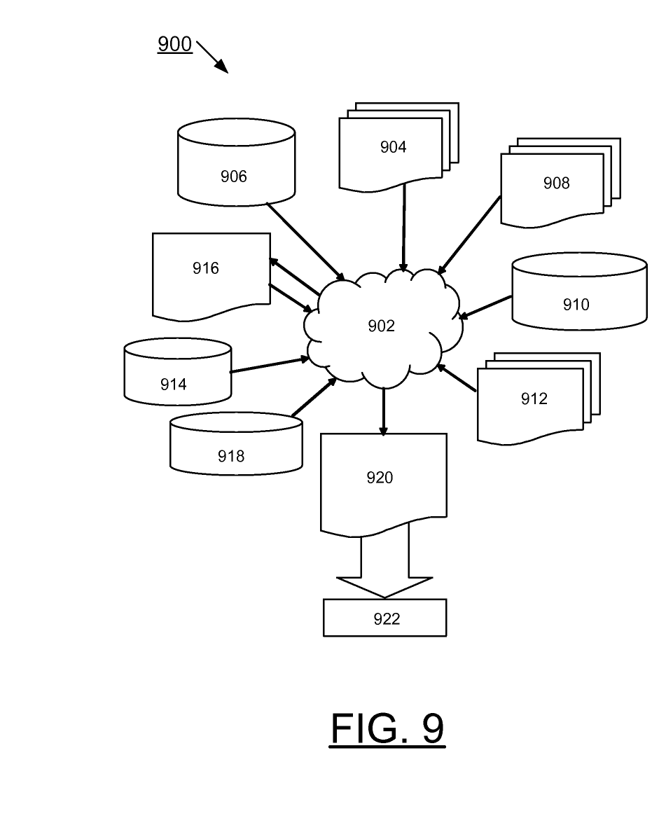

FIG. 9 shows a block diagram of an example design flow 900. Design flow 900 may vary depending on the type of IC being designed. For example, a design flow 900 for building an application specific IC (ASIC) may differ from a design flow 900 for designing a standard component. Design structure 902 is preferably an input to a design process 904 and may come from an IP provider, a core developer, or other design company or may be generated by the operator of the design flow, or from other sources. Design structure 902 comprises circuit 400 in the form of schematics or HDL, a hardware-description language, for example, Verilog, VHDL, C, and the like. Design structure 902 may be contained on one or more machine readable medium. For example, design structure 902 may be a text file or a graphical representation of circuit 100. Design process 904 preferably synthesizes, or translates, circuit 400 into a netlist 906, where netlist 906 is, for example, a list of wires, transistors, logic gates, control circuits, I/O, models, etc. that describes the connections to other elements and circuits in an integrated circuit design and recorded on at least one of machine readable medium. This may be an iterative process in which netlist 906 is resynthesized one or more times depending on design specifications and parameters for the circuit.

Design process 904 may include using a variety of inputs; for example, inputs from library elements 908 which may house a set of commonly used elements, circuits, and devices, including models, layouts, and symbolic representations, for a given manufacturing technology, such as different technology nodes, 32 nm, 45 nm, 90 nm, and the like, design specifications 910, characterization data 912, verification data 914, design rules 916, and test data files 918, which may include test patterns and other testing information. Design process 904 may further include, for example, standard circuit design processes such as timing analysis, verification, design rule checking, place and route operations, and the like. One of ordinary skill in the art of integrated circuit design can appreciate the extent of possible electronic design automation tools and applications used in design process 904 without deviating from the scope and spirit of the invention. The design structure of the invention is not limited to any specific design flow.

Design process 904 preferably translates an embodiment of the invention as shown in FIG. 4A along with any additional integrated circuit design or data (if applicable), into a second design structure 920. Design structure 920 resides on a storage medium in a data format used for the exchange of layout data of integrated circuits, for example, information stored in a GDSII (GDS2), GL1, OASIS, or any other suitable format for storing such design structures. Design structure 920 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 4A. Design structure 920 may then proceed to a stage 922 where, for example, design structure 920 proceeds to tape-out, is released to manufacturing, is released to a mask house, is sent to another design house, is sent back to the customer, and the like.

While the present invention has been described with reference to the details of the embodiments of the invention shown in the drawing, these details are not intended to limit the scope of the invention as claimed in the appended claims.

What is claimed is:

1. A method for implementing reduced noise coupling effects on single ended clocks comprising the steps of:
receiving an input clock signal;
continuously sampling received clock peaks and received clock valleys of the received input clock signal; and
generating a clock voltage reference based upon the sampled clock peaks and clock valleys of the received input clock signal.

2. The method for implementing reduced noise coupling effects on single ended clocks as recited in claim 1 wherein generating the clock voltage reference includes setting the clock voltage reference equal to an average (VT+VB)/2 where VT represents a value of the sampled clock peaks and VB represents a value of the sampled clock valleys.

3. The method for implementing reduced noise coupling effects on single ended clocks as recited in claim 1 wherein generating the clock voltage reference includes setting a falling clock voltage reference equal to VT−VPP/2 and setting a rising clock voltage reference equal to VB+VPP/2, where VT represents a value of the sampled clock peaks and VB represents a value of the sampled clock valleys and VPP represents a peak to peak voltage value of received input clock signal.

4. The method for implementing reduced noise coupling effects on single ended clocks as recited in claim 1 further includes providing an input AC coupling capacitor for receiving the input clock signal.

5. The method for implementing reduced noise coupling effects on single ended clocks as recited in claim 4 wherein continuously sampling received clock peaks and received clock valleys includes providing a sample and hold for receiving the AC coupled input clock signal.

6. The method for implementing reduced noise coupling effects on single ended clocks as recited in claim 4 further includes providing a unity gain buffer coupled to said sample and hold.

7. An apparatus for implementing reduced noise coupling effects on single ended clocks comprising:
a clock receiver including a clock voltage reference; said clock voltage reference being generated from received clock peaks and valleys of a received input clock signal; and
a clock voltage reference generator circuit for continuously sampling received clock peaks and the received clock valleys and for generating said clock voltage reference.

8. The apparatus for implementing reduced noise coupling effects on single ended clocks as recited in claim 7 wherein said clock receiver includes an input AC coupling capacitor for receiving and coupling the input clock signal.

9. The apparatus for implementing reduced noise coupling effects on single ended clocks as recited in claim 8 wherein said clock voltage reference generator circuit includes a sample and hold for receiving the AC coupled input clock signal.

10. The apparatus for implementing reduced noise coupling effects on single ended clocks as recited in claim 9 further includes a unity gain buffer coupled to said sample and hold.

11. The apparatus for implementing reduced noise coupling effects on single ended clocks as recited in claim 7 wherein said clock voltage reference is equal to an average (VT+VB)/2 where VT represents a value of the sampled clock peaks and VB represents a value of the sampled clock valleys.

12. The apparatus for implementing reduced noise coupling effects on single ended clocks as recited in claim 7 wherein said clock voltage reference includes a falling clock voltage reference equal to VT−VPP/2 and a rising clock voltage reference equal to VB+VPP/2, where VT represents a value of the sampled clock peaks and VB represents a value of the sampled clock valleys and VPP represents a peak to peak voltage value of received input clock signal.

13. A design structure embodied in a machine readable medium used in a design process, the design structure comprising:
a clock receiver including a clock voltage reference; said clock voltage reference being generated from received clock peaks and valleys of a received input clock signal; and
a clock voltage reference generator circuit for continuously sampling received clock peaks and the received clock valleys and for generating said clock voltage reference.

14. The design structure of claim 13, wherein the design structure comprises a netlist, which describes the circuit.

15. The design structure of claim 13, wherein the design structure resides on storage medium as a data format used for the exchange of layout data of integrated circuits.

16. The design structure of claim 13, wherein the design structure includes at least one of test data files, characterization data, verification data, or design specifications.

17. The design structure of claim 13, wherein said clock receiver includes an input AC coupling capacitor for receiving and coupling the input clock signal.

18. The design structure of claim 13, wherein said clock voltage reference generator circuit includes a sample and hold for receiving the AC coupled input clock signal.

19. The design structure of claim 18, further includes a unity gain buffer coupled to said sample and hold.

20. The design structure of claim 13, wherein said clock voltage reference is equal to an average (VT+VB)/2 where VT represents a value of the sampled clock peaks and VB represents a value of the sampled clock valleys.
